(19) United States
(12) Patent Application Publication
(10) Pub. No.: US 2015/0054018 A1
(43) Pub. Date: Feb. 26, 2015

(54) LIGHT-EMITTING DEVICE

(71) Applicant: TOYODA GOSEI CO., LTD., Kiyosu-shi (JP)

(72) Inventors: Yukiko Yabuta, Kiyosu-shi (JP); Yoshinori Masatsugu, Kiyosu-shi (JP); Toshimasa Hayashi, Kiyosu-shi (JP)

(73) Assignee: TOYODA GOSEI CO., LTD., Kiyosu-shi (JP)

(21) Appl. No.: 14/290,723

(22) Filed: May 29, 2014

(30) Foreign Application Priority Data
Aug. 21, 2013 (JP) 2013-171636

(51) Int. Cl. H01L 33/62; H01L 23/32

(52) U.S. Cl. CPC H01L 33/62; H01L 23/32
USPC 257/99

(57) ABSTRACT

A light-emitting device includes a case including a recessed portion, a lead frame that is housed in the case so as to be exposed in a bottom portion of the recessed portion and includes a first region, a second region and a third region arranged sandwiched between the first and second regions, a light-emitting element mounted in the first region and electrically connected to the third region via a first wire, and a hold-down member covering both ends in a width direction of an upper surface of the third region so as to hold down the third region from above. One end in a longitudinal direction of the third region protrudes outside of the case. The hold-down member is formed so as to contact with an inner surface of a sidewall of the recessed portion at an other end in the longitudinal direction of the third region.

The present application is based on Japanese patent application No. 2013-171636 filed on Aug. 21, 2013, the entire contents of which are incorporated herein by reference.

### BACKGROUND OF THE INVENTION

1. Field of the Invention

The invention relates to a light-emitting device.

2. Description of the Related Art

An LED light emitting device is known in which a raised portion (or a convex portion) is formed on an inner wall of a case thereof (see e.g. JP-A-2013-12613 and JP-B-5119621 and JP-B-3466817). JP-A-2013-12613 states that the raised portion formed on the inner wall of the case can reduce a stress occurring in a sealing resin and can prevent the separation of a lead frame from the case.

JP-B-5119621 states that the raised portion formed on the inner wall of the case can effectively prevent a package material from leaking in the vicinity of the lead frame during the manufacture of the package. Also, JP-B-3466817 states that the raised portion formed on the inner wall of the case can prevent the separation of the lead frame from the case, which may be caused by a shearing force applied to the lead frame upon cutting the lead frame.

### SUMMARY OF THE INVENTION

It is an object of the invention to provide a light-emitting device that is configured so as to more surely prevent the separation of the lead frame from the case.

(1) According to one embodiment of the invention, a light-emitting device comprises:

a case comprising a recessed portion:

a lead frame that is housed in the case so as to be exposed in a bottom portion of the recessed portion and comprises a first region, a second region and a third region arranged to be sandwiched between the first and second regions;

a light-emitting element that is mounted in the first region and is electrically connected to the third region via a first wire; and

a hold-down member covering both ends in a width direction of an upper surface of the third region so as to hold down the third region from above,

wherein one end in a longitudinal direction of the third region protrudes outside of the case, and

wherein the hold-down member is formed so as to contact with an inner surface of a sidewall of the recessed portion at an other end in the longitudinal direction of the third region.

In the above embodiment (1) of the invention, the following modifications and changes can be made.

(i) The light-emitting device further comprises a second light-emitting element that is mounted in the second region and is electrically connected to the third region via a second wire.

(ii) The hold-down member is configured so as to separate a region where the first wire is connected to the third region and a region where the second wire is connected to the third region.

(iii) The hold-down member is formed integrally with the case and comprises a same material as the case.

(iv) A width of the third region in a region protruding outside of the case is a same as in a region of the third region exposed at the bottom portion of the recessed portion.

### Effects of the Invention

According to one embodiment of the invention, a light-emitting device can be provided that is configured so as to more surely prevent the separation of the lead frame from the case.

### BRIEF DESCRIPTION OF THE DRAWINGS

Next, the present invention will be explained in more detail in conjunction with appended drawings, wherein:

FIG. 1 is a perspective view showing a light-emitting device in a first embodiment;

FIG. 2A is a top view showing the light-emitting device in the first embodiment;

FIG. 2B is a vertical cross-sectional view showing the light-emitting device taken along a line A-A in FIG. 2A;

FIG. 3 is a top view showing the light-emitting device before being separated from a metal frame;

FIG. 4A is a conceptual diagram illustrating a horizontal positional relation between a hold-down member and a third region;

FIG. 4B is a conceptual diagram illustrating a horizontal positional relation between the hold-down member in a modification and the third region;

FIG. 5 is a vertical cross-sectional view showing a light-emitting device having an alternative lead frame;

FIG. 6 is a perspective view showing a light-emitting device in a second embodiment;

FIG. 7A is a top view showing the light-emitting device in the second embodiment;

FIG. 7B is a vertical cross-sectional view showing the light-emitting device taken along a line B-B in FIG. 7A; and

FIG. 8 is a conceptual diagram illustrating a horizontal positional relation between a hold-down member 25 and a third region 12c.

### DETAILED DESCRIPTION OF THE PREFERRED EMBODIMENTS

### First Embodiment

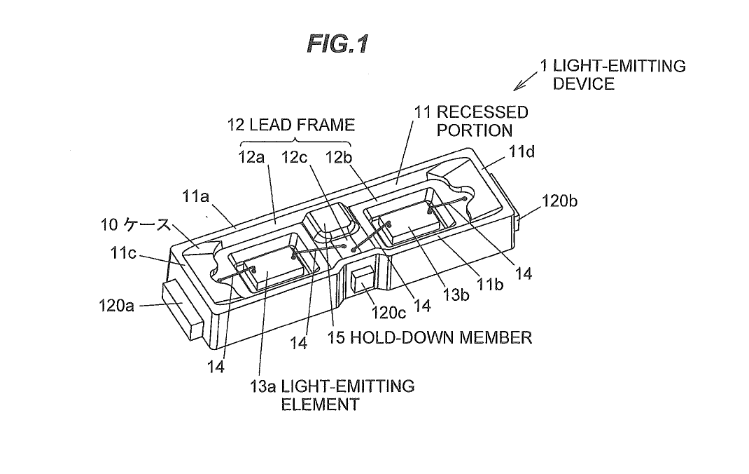

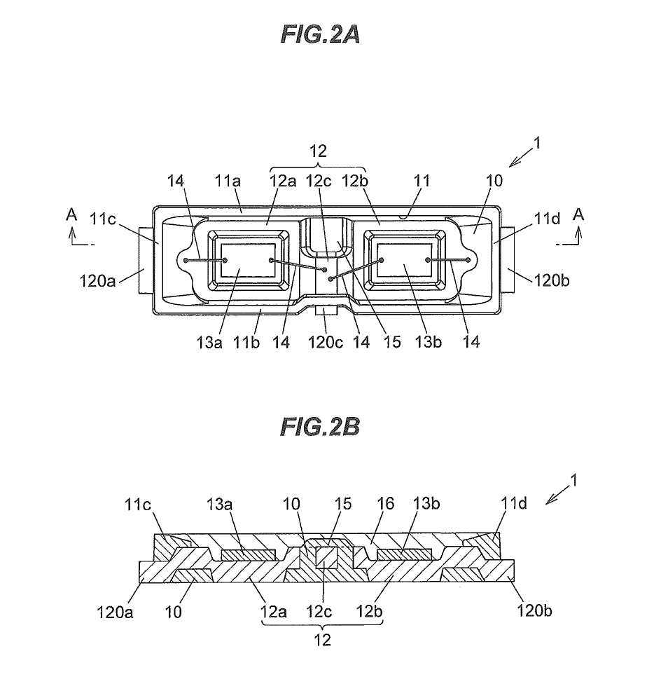

FIG. 1 is a perspective view showing a light-emitting device 1 in the first embodiment. FIG. 2A is a top view showing the light-emitting device 1 in the first embodiment. FIG. 2B is a vertical cross-sectional view showing the light-emitting device 1 taken along the line A-A in FIG. 2A.

The light-emitting device 1 is provided with a case 10 having a recessed portion (or a concave portion) 11, a lead frame 12 which is housed in the case 10 so as to be exposed in a bottom portion of the recessed portion 11 and has a first region 12a, a second region 12b and a third region 12c arranged to be sandwiched between the first region 12a and the second region 12b, light-emitting elements 13a and 13b which are mounted in the first region 12a and the second region 12b, respectively, and are electrically connected to the third region 12c via wires 14, a hold-down member 25 covering both ends in a width direction of an upper surface (of a part) of the third region 12c to hold down the third region 12c from above, and a sealing material 16 filled in the recessed portion 11 to seal the light-emitting elements 13a and 13b.

Meanwhile, the illustration of the sealing material 16 is omitted in FIG. 1 and FIG. 2A.

One end in the longitudinal direction of the third region 12c protrudes outside of the case 10. The hold-down member 15 is formed so as to contact with an inner surface of a sidewall 11a of the recessed portion 11 at another end in the longitudinal direction of the third region 12c.

The case 10 is formed of, e.g., a thermoplastic resin such as polyphthalamide resin, LCP (liquid crystal polymer) or PCT (polycyclohexylene dimethylene terephthalate) or a thermosetting resin such as silicone resin, modified silicone resin, epoxy resin or modified epoxy resin. The case 10 may contain light-reflecting particles of titanium dioxide, etc., to improve light reflectance.

The case 10 is formed by, e.g., insert molding which is performed by injecting a resin into a mold having the lead frame 12 already inserted therein.

The recessed portion 11 of the case 10 has a substantially rectangular shape in a plan view in which sidewalls 11a and 11b are sidewalls along the longitudinal direction of the substantially rectangular shape and sidewalls 11c and 11d are sidewalls along the lateral direction.

The entire lead frame 12 or the surface thereof is formed of a conductive material such as Ag, Cu or Al. The first region 12a, the second region 12b and the third region 12c penetrate the sidewalls 11c, 11d and 11b, respectively, of the recessed portion 11 and protrude outside of the case 10. The portions of the first region 12a, the second region 12b and the third region 12c protruding outside of the case 10 are respectively defined as protruding portions 120a, 120b and 120c.

Each of the light-emitting elements 13a and 13b is, e.g., an LED chip having a chip substrate and a crystal layer in which a light-emitting layer is sandwiched between cladding layers. The light-emitting elements 13a and 13b may be a face-up LED chip with the crystal layer facing upward or a face-down LED chip with the crystal layer facing downward. Alternatively, light-emitting elements other than LED chips may be used.

The light-emitting element 13a is electrically connected to the first region 12a and the third region 12c via the wires 14. Alternatively, the light-emitting element 13a and the first region 12a may be connected by other means such as conductive bump in place of the wire 14.

The light-emitting element 13b is electrically connected to the second region 12b and the third region 12c via the wires 14. Alternatively, the light-emitting element 13b and the second region 12b may be connected by other means such as conductive bump in place of the wire 14.

The wire 14 is a bonding wire formed of a conductive material such as Au, Ag, Al or Cu.

The sealing resin 16 is formed of, e.g., a transparent resin such as silicone-based resin or epoxy-based resin. In addition, the sealing resin 16 may contain phosphor in the form of particles. For example, when emission color of the light-emitting elements 13a and 13b is blue and fluorescence color of the phosphor contained in the sealing resin 16 is yellow, emission color of the light-emitting device 1 is white.

The hold-down member 15 can prevent the third region 12c of the lead frame 12 from separating from the case 10 by holding down the third region 12c from above.

In the lead frame 12, the third region 12c is a region in which the light-emitting device is not mounted and to which only the wires 14 are connected, and the third region 12c has an area significantly smaller than the first region 12a or the second region 12b. The third region 12c is thus likely to separate from the case 10 when a load is applied due to a weight applied upon connecting (or wire-bonding) the wires 14 to the lead frame 12 or due to stress generated upon cutting (or lead-cutting) the third region 12c off from a metal frame 20 as described later. In this regard, the separation preventing effect of the hold-down member 15 is important.

In addition, a portion of the third region 12c on the side of the protruding portion 120c penetrates the sidewall 11b of the recessed portion 11 of the case 10 and is thereby relatively firmly fixed by the case 10. This causes the third region 12c to be likely to separate at an end portion opposite to the protruding portion 120c. In order to effectively prevent the separation of the third region 12c, the hold-down member 15 is formed so as to contact with the sidewall 11a of the recessed portion 11.

Although a material of the hold-down member 15 is not specifically limited, it is preferable that the hold-down member 15 be formed integrally with the case 10 using the same material as the case 10. In case that the hold-down member 15 is formed integrally with the case 10, the third region 12c can be held down more firmly and can be prevented from separating from the case 10. In addition, when the hold-down member 15 is formed of the same highly light reflective material as the case 10, the hold-down member 15 also serves as a reflector and allows light extraction efficiency of the light-emitting device 1 to be improved.

When the hold-down member 15 and the case 10 are formed integrally, for example, the hold-down member 15 and the case 10 are formed by injection molding using a mold corresponding to the shapes of the hold-down member 15 and the case 10. When the hold-down member 15 and the case 10 are formed separately, for example, the case 10 is injection-molded and the hold-down member 15 is then formed by dropping a material.

The light-emitting device 1 may be configured such that only one wire 14 is connected to the third region 12c. Compared to such a configuration, the third region 12c is more likely to separate from the case 10 due to wire bonding when two or more wires 14 are connected to the third region 12c and the third region 12c is used as a wire-linking portion. The separation prevention effect of the hold-down member 15 is important particularly in such a case.

In addition, in the example shown in FIGS. 1 to 2B, the third region 12c has a substantially rectangular parallelepiped shape and the width of the third region 12c is the same at a portion exposed from the bottom portion of the case 10 and at the protruding portion 120c as a portion protruding to the outside of the case 10. Although the shape of the third region 12c is not specifically limited, the third region 12c is likely to separate from the case 10 when having a long and thin shape as shown in FIGS. 1 to 2B. Therefore, the separation prevention effect of the hold-down member 15 is important.

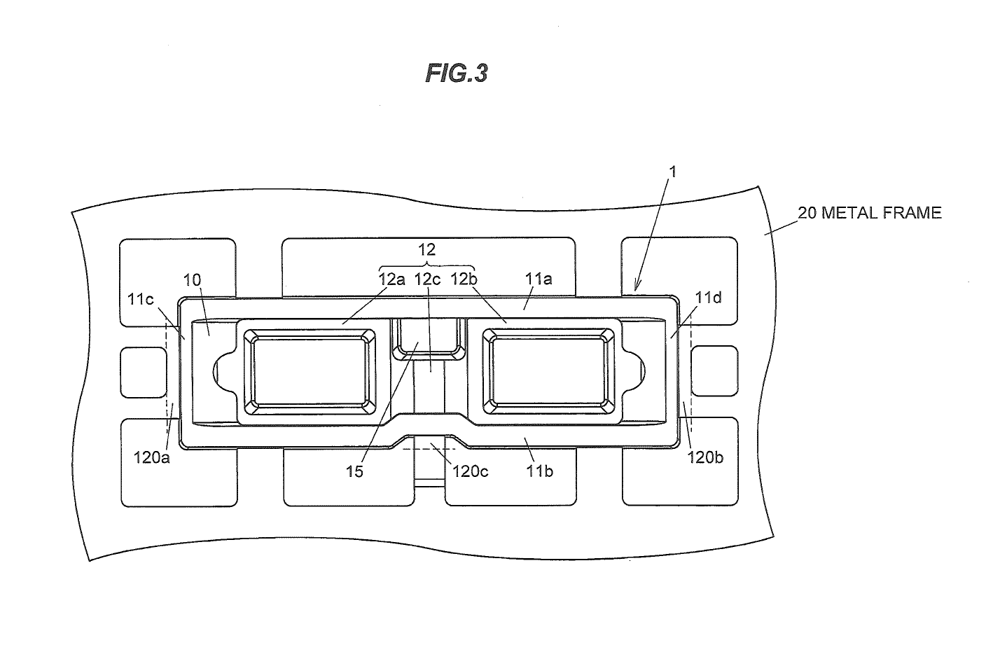

FIG. 3 is a top view showing the light-emitting device 1 before being separated from the metal frame 20. The metal frame 20 is a sheet-like frame in which plural lead frames are arranged.

The lead frame 12 is cut off from the metal frame 20 at dotted lines indicating boundaries between the metal frame 20 and the protruding portion 120a, between the metal frame 20 and the protruding portion 120b and between the metal frame 20 and the protruding portion 120c, thereby separating the light-emitting device 1 from the metal frame 20.

Meanwhile, the shape of and the cutting position on the metal frame 20 are only an example. In addition, illustrations of the light-emitting elements 13a and 13b, the wires 14 and the sealing material 16 are omitted in FIG. 3. In FIG. 3, a double line illustrated in a region of the metal frame 20 under the protruding portion 120c indicates a level difference formed on the metal frame 20. Since the third region 12c in the first embodiment is located higher than the bottom surface of the lead frame 12, the level difference is provided. Such a level difference is not required when the third region 12c is located at the same level as the metal frame 20.

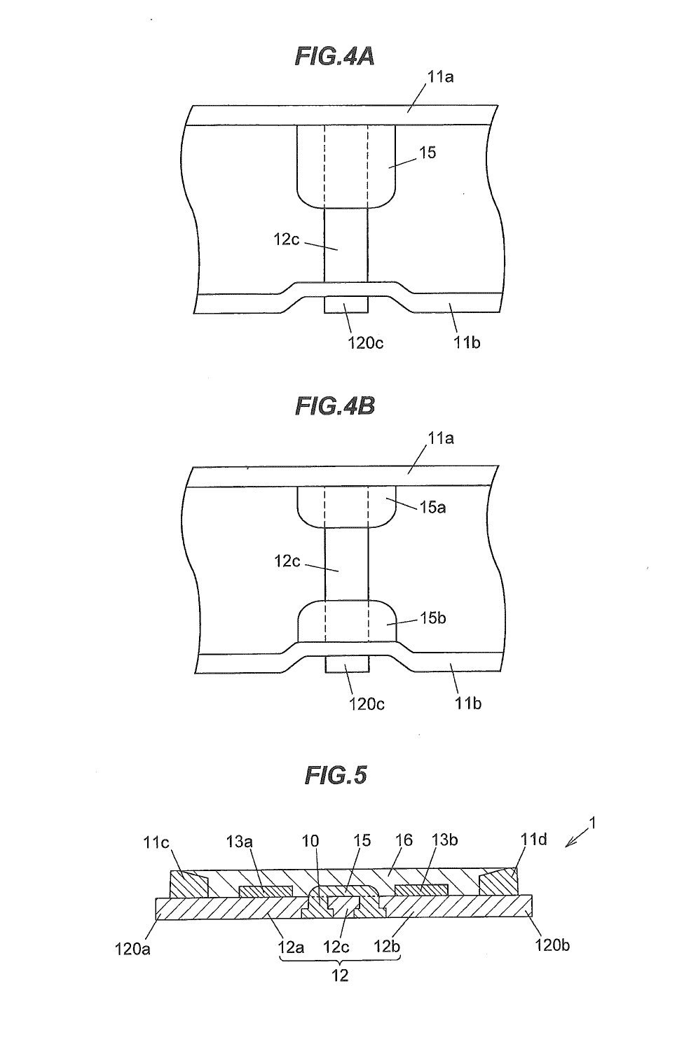

FIG. 4A is a conceptual diagram illustrating a horizontal positional relation between the hold-down member 15 and the third region 12c. The dotted lines in the drawing indicate rims (widthwise edges) of the third region 12c at a portion covered with the hold-down member 15.

As shown in FIG. 4A, the hold-down member 15 is provided in contact with an inner surface of the sidewall 11a, which is a sidewall of the recessed portion 11 on a side from which the protruding portion 120c does not protrude, so as to cover both ends in the width direction of the upper surface (of a part) of the third region 12c.

FIG. 4B is a conceptual diagram illustrating a horizontal positional relation between the hold-down member 15 in a modification and the third region 12c. In this modification, the hold-down member 15 includes a portion 15a in contact with the inner surface of the sidewall 11a and a portion 15b in contact with the sidewall 11b.

As shown in FIG. 4B, the portion 15a of the hold-down member 15 covers both ends in the width direction of the upper surface (of a part) of the third region 12c.

FIG. 5 is a vertical cross-sectional view showing the light-emitting device 1 having an alternative lead frame 12. The lead frame 12 may have a plate-like shape as shown in FIG. 5. In this case, the height of the lead frame 12 is substantially the same at the portions mounting the light-emitting elements 13a and 13b and at the third region 12c.

### Second Embodiment

The second embodiment is different from the first embodiment in a shape of the hold-down member which holds down the third region from above. Meanwhile, the explanation of the same features as the first embodiment will be omitted or simplified.

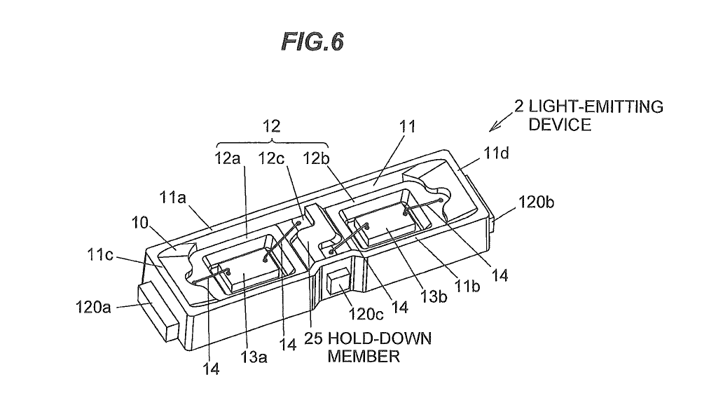

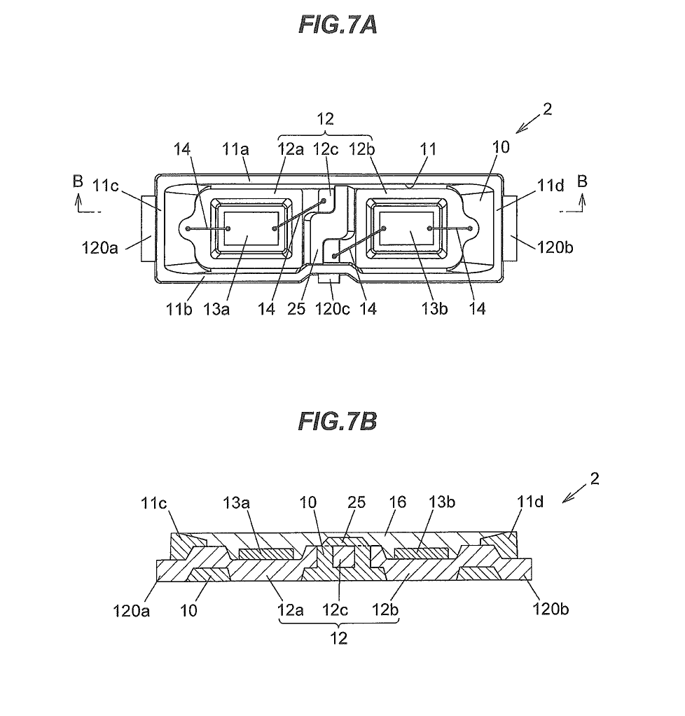

FIG. 6 is a perspective view showing a light-emitting device 2 in the second embodiment. FIG. 7A is a top view showing the light-emitting device 2 in the second embodiment. FIG. 7B is a vertical cross-sectional view showing the light-emitting device 2 taken along the line B-B in FIG. 7A.

The light-emitting device 2 is provided with the case 10 having the recessed portion 11, the lead frame 12 which is housed in the case 10 so as to be exposed in the bottom portion of the recessed portion 11 and has the first region 12a, the second region 12b and the third region 12c arranged to be sandwiched between the first region 12a and the second region 12b, the light-emitting elements 13a and 13b which are mounted in the first region 12a and the second region 12b, respectively, and are electrically connected to the third region 12c via the wires 14, a hold-down member 25 covering both ends in the width direction of the upper surface (of a part) of the third region 12c to hold down the third region 12c from above, and the sealing material 16 filled in the recessed portion 11 to seal the light-emitting elements 13a and 13b.

Meanwhile, the illustration of the sealing material 16 is omitted in FIG. 6 and FIG. 7A.

The hold-down member 25 can prevent the third region 12c of the lead frame 12 from separating from the case 10 by holding down the third region 12c from above in the same manner as the hold-down member 15 in the first embodiment.

In the light-emitting device 2, the third region 12c is separated by the hold-down member 25 such that a region in which the wire 14 connected to the light-emitting element 13a is connected is separated from a region in which the wire 14 connected to the light-emitting element 13b is connected.

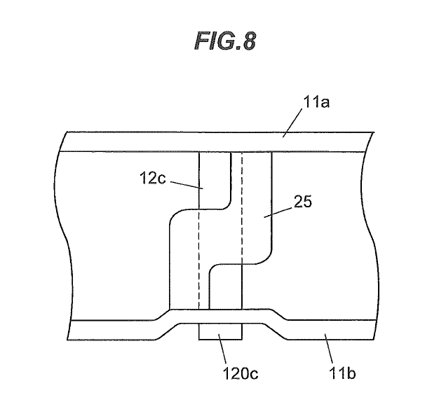

FIG. 8 is a conceptual diagram illustrating a horizontal positional relation between the hold-down member 25 and the third region 12c. The dotted lines in the drawing indicate widthwise edges of the third region 12c at a portion covered with the hold-down member 25.

As shown in FIG. 8, the hold-down member 25 is formed so as to contact both with the inner surface of the sidewall 11a which is a sidewall of the recessed portion 11 on a side from which the protruding portion 120c does not protrude and with the inner surface of the sidewall 11b which is a sidewall of the recessed portion 11 on a side from which the protruding portion 120c protrudes, so as to cover both ends in the width direction of the upper surface (of a part) of the third region 12c.

Since the hold-down member 25 has a shape dividing the recessed portion 11 so that a region for mounting the light-emitting element 13a is separated from a region for mounting the light-emitting element 13b, the hold-down member 25 shows an excellent function when used as a reflector. In detail, it is possible to improve light extraction efficiency by diffusely reflecting light of the light-emitting elements 13a and 13b by the hold-down member 25. In addition, by diffusely reflecting the light which is emitted from the light-emitting elements 13a and 13b at a large angle with respect to the vertical direction, it is possible to suppress variation in light path length in the sealing material 16 containing phosphors and thereby to improve uniformity of chromaticity.

In addition, by providing the hold-down member 25 so that the upper surface thereof is higher than the upper surface of the sealing material 16, it is possible to use the hold-down member 25 to dam the sealing material 16. In this case, for example, color of phosphor added to the sealing material 16 for sealing the light-emitting element 13a can be different from color of phosphor added to the sealing material 16 for sealing the light-emitting element 13b.

### Effects of the Embodiments

In the first and second embodiments, the hold-down member s 15, 25 are each used to hold down the third region 12c of the lead frame 12 from above and thereby to allow separation of the third region 12c from the case to be effectively suppressed.

Although the embodiments of the invention have been described, the invention is not intended to be limited to the embodiments and the various kinds of modifications can be implemented without departing from the gist of the invention.

In addition, the invention according to claims is not to be limited to the above-mentioned embodiments. Further, all combinations of the features described in the embodiments are not necessary to solve the problem of the invention.

What is claimed is:

1. A light-emitting device, comprising:
a case comprising a recessed portion:
a lead frame that is housed in the case so as to be exposed in a bottom portion of the recessed portion and comprises a first region, a second region and a third region arranged to be sandwiched between the first and second regions;
a light-emitting element that is mounted in the first region and is electrically connected to the third region via a first wire; and
a hold-down member covering both ends in a width direction of an upper surface of the third region so as to hold down the third region from above,
wherein one end in a longitudinal direction of the third region protrudes outside of the case, and
wherein the hold-down member is formed so as to contact with an inner surface of a sidewall of the recessed portion at an other end in the longitudinal direction of the third region.

2. The light-emitting device according to claim 1, further comprising a second light-emitting element that is mounted in the second region and is electrically connected to the third region via a second wire.

3. The light-emitting device according to claim 2, wherein the hold-down member is configured so as to separate a region where the first wire is connected to the third region and a region where the second wire is connected to the third region.

4. The light-emitting device according to claim 1, wherein the hold-down member is formed integrally with the case and comprises a same material as the case.

5. The light-emitting device according to claim 1, wherein a width of the third region in a region protruding outside of the case is a same as in a region of the third region exposed at the bottom portion of the recessed portion.
